(19) United States
(12) Patent Application Publication
(10) Pub. No.: US 2005/0139819 A1
(43) Pub. Date: Jun. 30, 2005

(54) Process for fabricating nanoelectronic device by intermittent exposure

(75) Inventors: Gwo-Jen Hwang, Hsinchu City (TW); Yi-Pin Fang, Hsinchu City (TW); Ya-Chang Chou, Hsinchu City (TW); Shu-Fen Hu, Hsinchu City (TW)

Correspondence Address: BACON & THOMAS, PLLC, 625 SLATERS LANE, FOURTH FLOOR, ALEXANDRIA, VA, 22314, US

(73) Assignee: Industrial Technology Research Institute, Judung Township (TW)

(21) Appl. No.: 10/998,603

(22) Filed: Nov. 30, 2004

(30) Foreign Application Priority Data
Dec. 26, 2003 (TW) 092137191

(51) Int. Cl. H01L 31/062; H01L 29/76

(52) U.S. Cl. 257/14; 257/25; 438/962

(57) ABSTRACT

A process for fabricating a nanoelectronic device by intermittent exposure is disclosed, consisting the steps of: providing a substrate on which a conductor or semiconductor thin film having a photoresist layer coated is formed; exposing the photoresist layer by lithography with a lithographic pattern which includes at least one noncontinuous quantum dot, a first electrode and a second electrode, in which the noncontinuous quantum dots are linearly arranged and sandwiched between the first electrode and the second electrode; and etching the thin film to form a quantum island group of linked quantum islands having both ends connected to the first electrode and the second electrode respectively so that the width of the quantum island is larger than the width of tunnel barriers positioned on the both sides of the quantum islands. A nanoelectronic device constructed according to the process is also disclosed.

### BACKGROUND OF THE INVENTION

1. Field of the Invention

The present invention relates to a process for fabricating a nanoelectronic device by intermittent exposure and a construction of the nanoelectronic device, and more particularly to a process for fabricating a single electron transistor and a construction of the single electron transistor.

2. Description of Related Art

Semiconductor fabricating technology has developed at an astounding speed whereby the size of components and devices has shrunk continually over recent years. In view of the development from thousands of individual transistors in 1970 to a single chip composed of tens of millions transistors at present, the power consumption of the device has to be maintained in a controllable range of a few Watts. However, the power consumption of the device is proportional to the number of electrons generating an electric current. Since the electric current of a single electron transistor (SET) is caused by a single electron, the power consumption is relatively very low. Thus, the single electron device will be a chip composed of tens of millions transistors and become the main stream of a new generation of electronic devices in the 21st century. Traditional complementary metal oxide field effect transistors are featured by their high-speed transmission circuits and have the capability of functioning as an outputting interface while the single electron transistor is featured by its low power consumption and high-density package. Flexible utilization of these two types of devices in a fitting manner will bring about an integrated circuit having high speed, low power consumption and high device density. Contemporary research for the single electron transistors can be categorized in accordance with the material into the following: (1) group III-V materials, (2) metal materials, (3) superconductor materials, and (4) silicon materials, in which the silicon materials will be more suitable for future developments of VLSI and ULSI integrated circuits.

The single electron transistor is constituted primarily by a quantum island connected to two electrodes via a tunnel barrier and a third electrode disposed close to the quantum island. The third electrode controls the potential of the quantum island. The single electron transistor controls the movement of the respective electrons by Coulomb-blockade effect to result in a device having very low power consumption. In addition, the nano-scaled single electron transistor occupies a very small area so that the device density is higher than that of the known integrated circuits. Thus, the single electron transistor will become a key member in the rapid development of the nanoelectronic devices.

In the prior art using semiconductor technology to fabricate a single electron transistor on a silicon substrate, the single electron transistor has only one single quantum island. When the device density increases, interference between signals of the device becomes significant. This will be one of the factors that restrict the nanoelectronic device from continued shrinking. Recently, research into interference among a plurality of quantum islands has attracted particular attention from the industry. As for the single electron transistor having a single quantum island, Yasuo Takahashi taught in U.S. Pat. No. 5,04,154, entitled “Method of manufacturing Coulomb blockade element using thermal oxidation”, which relates to a method for defining a single electron transistor by the counter of a silicon thin film. As shown in FIG. 1, the method uses a semiconductor substrate 2 on which a barrier oxide thin film 3 is disposed. Then, a silicon oxide layer 5 is formed by thermal oxidation so that the barrier oxide thin film 3 and the silicon oxide layer 5 sandwiches a silicon thin film 4. Then, a wire 10 and two electrodes 11, 12 are formed on the silicon thin film 4 by etching. The wire provides a single quantum island for confining an electric charge. The quantum island constructed on the silicon thin film 4 is formed by thermal oxidation of different oxidation rates caused by different stresses on the wire. As a result, the wire portion nearby the electrodes has a narrow width to form a tunnel barrier between the single quantum island and the electrodes, as in a cross-sectional view shown in FIG. 2. Such a technique is suited for fabricating a single electron transistor having a single quantum island, but fails to fabricate a single electron transistor having quantum islands linked up with each other.

Therefore, it is desirable to provide an improved process for fabricating a nanoelectronic device by intermittent exposure to mitigate and/or obviate the aforementioned problems.

### SUMMARY OF THE INVENTION

An object of the present invention is to provide a process for fabricating nanoelectronic devices by intermittent exposure so as to simply produce a nanoelectronic device having a single or a plurality of quantum islands. The prior art fails to produce a single electron transistor having quantum islands, and also, the method for making the same is limited by the substrate material.

Another object of the present invention is to provide a nanoelectronic device constructed of a single electron transistor having one or more than one quantum island by a simple process. Because there are quantum islands, design of device circuits will become more flexible.

To attain the aforesaid object, a process for fabricating a nanoelectronic device by intermittent exposure according to the present invention comprises: providing a substrate on which a conductor or semiconductor thin film having a photoresist layer coated is formed; exposing the photoresist layer by lithography with a lithographic pattern which includes at least noncontinuous quantum dots, a first electrode and a second electrode, in which the noncontinuous quantum dots are linearly arranged and sandwiched between the first electrode and the second electrode; and etching the conductor or semiconductor thin film to form a quantum island group of linked quantum islands, the quantum island group having both ends connected to the first electrode and the second electrode respectively, in which at least one quantum island and at least two tunnel barriers on the both sides of the quantum island are included and the width of the quantum dots is wider than the width of the tunnel barriers.

To attain the aforesaid object, a nanoelectronic device constructed according to the present invention is composed of a conductor or semiconductor thin film formed on a substrate, comprising a first electrode, a second electrode, at least one quantum island formed by lithography to define noncontinuous quantum dots and linearly arranged between the first electrode and the second electrode, and at least two tunnel barriers formed by the proximity effect of lithography and disposed on the both sides of the quantum island so that the surface width of the tunnel barriers is narrower than the surface width of the quantum island to link up with the other quantum island, the first electrode, or the second electrode.

In a process for fabricating nanoelectronic devices by intermittent exposure according to the present invention, the substrate is not specifically defined. The substrate may be a silicon substrate, a glass substrate, a polymer substrate or an organic substrate. The material of the conductor or semiconductor thin film is not specifically defined, which may be a monocrystalline silicon, a polycrystalline silicon, a metal or a III-V material. In step (b), the lithographic pattern designed for the lithography has n (more than three in number) quantum dots so as to form n-2 quantum islands. The arrangement of the quantum dots is not specifically defined, but preferably a linear arrangement, a triangular arrangement, a square arrangement, a rectangular arrangement or a hexagonal arrangement. The shape of the quantum dots is not specifically defined, but preferably is a circle or an ellipse. In forming the Coulomb-blockade portion of the single electron transistor, the quantum dots have a single electron passed through the quantum islands formed after an etching. The etching technique used in the present process is to facilitate formation of a patterned thin film at the nano scale, and may be an electron cyclotron resonance (ECR) etching or a reactive ion etching. The lithography technique used herein is to provide the proximity effect with the photoresists, having a resolution close to the nano scale. To this end, there are electron-beam lithography, X-ray lithography, micro focused ion beam lithography and pulsed excimer laser-induced extreme-ultraviolet lithography currently available. Preferably, the electron-beam lithography is used so that the photoresist layer is directly written by intermittent exposure.

In the processing steps, step (d) of depositing an oxide insulation layer over the conductor or semiconductor thin film is included after step (c). Step (e) of forming at least a third electrode on the oxide insulation layer is further included after step (d), the third electrode serving as a main gate or side gate for controlling the potential of the quantum islands.

In the present process, the first electrode and the second electrode can serve as the drain and the source, or alternatively, metal line surrounding the quantum islands. In step (a), the photoresist layer is preferably a negative photoresist material while the lithographic pattern in step (b) is formed by photolithographic exposure.

In a nanoelectronic device constructed by the present invention, the substrate is not specifically defined. The substrate may be a silicon substrate, a glass substrate, a polymer substrate or an organic substrate to be applied more broadly, as compared with the prior quantum island formed by thermal oxidation. Furthermore, because the substrate in contact with the conductor or semiconductor thin film needs no oxide layer, the material of the conductor or semiconductor thin film is not specifically defined which may be a monocrystalline silicon, a polycrystalline silicon, a metal or a III-V material. If the first electrode and the second electrode are formed on the semiconductor thin film, they serve as the drain and the source respectively. If the first electrode and the second electrode are formed on the conductor thin film, only a metal line is found. An etching technique is used to form a construction of the quantum islands after the lithography causes the photoresists to generate the proximity effect. The quantum islands have a resolution close to the nano scale. To this end, there are electron-beam lithography, X-ray lithography, micro focused ion beam lithography and pulsed excimer laser-induced extreme-ultraviolet lithography currently available. Preferably, the electron-beam lithography is used so that the photoresist layer is directly written by intermittent exposure.

When the thin film is made of the semiconductor material, an oxide insulation layer is formed over the semiconductor thin film, and then, at least an electrode which may be the main gate or the side gate is further formed on the oxide insulation layer. When the thin film is made of the conductor material, an oxide insulation layer is formed over the conductor thin film, and then, a window is formed at an appropriate position so that another metal line contacts with the conductor thin film via the window.

Other objects, advantages, and novel features of the invention will become more apparent from the following detailed description when taken in conjunction with the accompanying drawings.

### BRIEF DESCRIPTION OF THE DRAWINGS

FIG. 1 is a schematic view of a conventional method for manufacturing a Coulomb-blockade element of a nanoelectronic device using thermal oxidation.

FIG. 2 is a cross-sectional view of a conventional method for manufacturing a Coulomb-blockade element of a nanoelectronic device using thermal oxidation.

FIG. 3 is a schematic view of a photographic pattern design of a nanoelectronic device fabricated according to a preferred embodiment of the present invention.

FIG. 4a is an SEM diagram illustrating a construction of a Coulomb-blockade element of a nanoelectronic device fabricated by photolithography, according to a preferred embodiment of the present invention.

FIG. 4b is a top view of a structure of a Coulomb-blockade element of a nanoelectronic device fabricated according to a preferred embodiment of the present invention.

FIG. 5 is a schematic view of a photographic pattern design of a nanoelectronic device fabricated according to another preferred embodiment of the present invention.

FIG. 6a is an SEM diagram illustrating a structure of a Coulomb-blockade element of a nanoelectronic device fabricated according to another preferred embodiment of the present invention by photolithography.

FIG. 6b is a top view of a construction of a Coulomb-blockade element of a nanoelectronic device fabricated according to another preferred embodiment of the present invention.

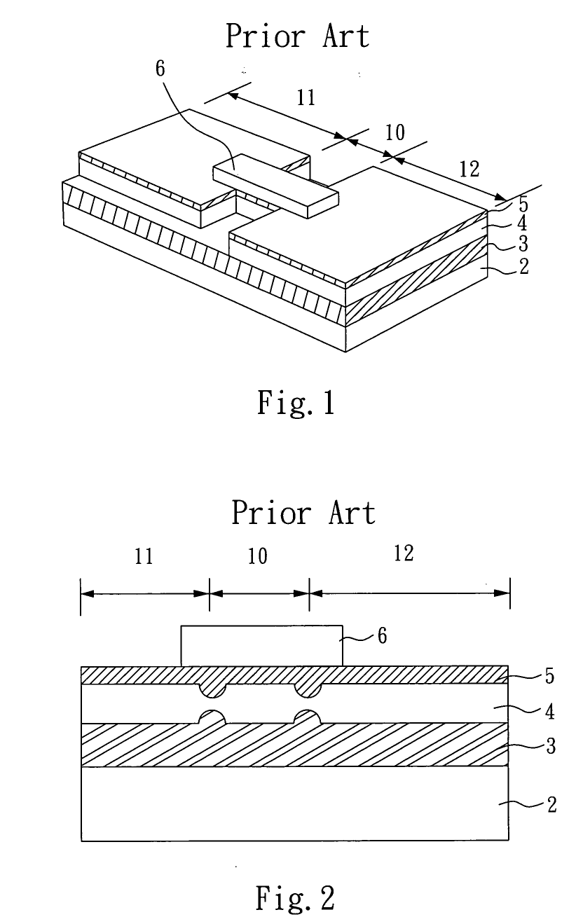

### DETAILED DESCRIPTION OF THE PREFERRED EMBODIMENT

Two preferred embodiments of the present invention will now be described to illustrate the technical contents involved in the present invention.

### Embodiment 1

### Fabrication of a Single Electron Transistor Having a Single Quantum Island

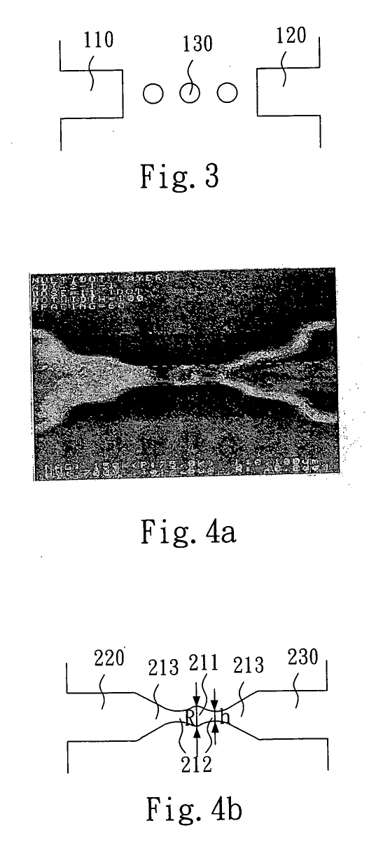

In a process for fabricating a nanoelectronic device of this embodiment, a substrate is provided at the beginning. Oxygen is implanted in the substrate by means of an ion implanting apparatus to form a buried oxide layer served as an insulation layer so that a silicon thin film is formed over the substrate, and then, a negative photoresist layer is coated on the silicon thin film. The photoresist layer is directly written by electron-beam lithography to result in a scanning pattern having a first electrode pattern (the source pattern) 110, a second electrode pattern (the drain pattern) 120 and three noncontinuous quantum dots 130 linearly arranged between the first electrode pattern 110 and the second electrode pattern 120, as shown in FIG. 3. Then, the photoresist layer is developed to have linked quantum dots 130 as a result of the proximity effect that occurred during the lithography, as shown in FIG. 4a. In other words, scattering of electrons incident into the photoresists and coming back from the substrate to the photoresist layer brings about a Gaussian distribution for the concentration of the electron beams. The proximity effect caused by the electron-beam lithography is affected by the electron beam exposure, the size of the quantum dots and energy. An etching is processed as shown in FIG. 4b, wherein the silicon thin film forms a quantum island 211 and two tunnel barriers 212 on respective sides of the quantum island 211. The two tunnel barriers 212 are connected to contacts 213 respectively, and then connected to the first electrode 220 and the second electrode 230 respectively, wherein the width h of the tunnel barriers 212 is narrower than the width R of the quantum island 211. The contacts 213 are formed at the position of the ellipse-shape quantum dots 130 in FIG. 3. Then, the silicon thin film is etched by reactive ion etching technique, and a gate oxide layer is deposited over the silicon thin film so as to further form a polysilicon gate on the gate oxide layer, the polysilicon gate being positioned above the quantum island 211 in an opposite manner. Consequently, a single electron transistor having the gate, the source and the drain is fabricated.

### Embodiment 2

### Fabrication of a Single Electron Transistor Having Two Quantum Islands

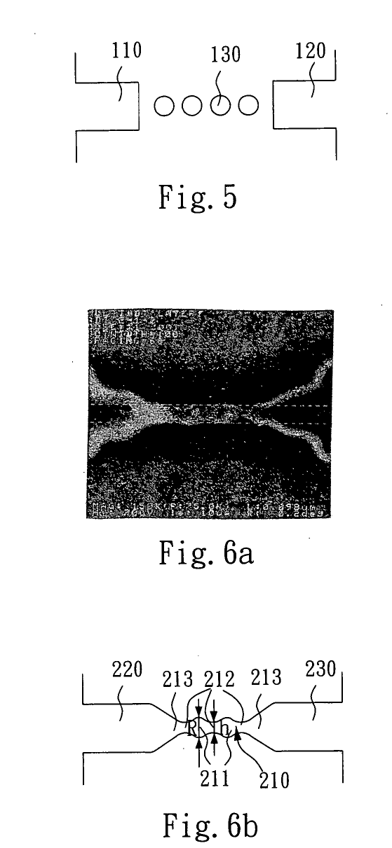

In a process for fabricating a nanoelectronic device of this embodiment, a substrate is provided at the beginning. Oxygen is implanted in the substrate by means of an ion implanting apparatus to form a buried oxide layer serving as an insulation layer so that a silicon thin film is formed over the substrate, and then, a negative photoresist layer is coated on the silicon thin film. The photoresist layer is patterned by electron-beam lithography to result in an exposed pattern having a first electrode pattern (the source pattern) 110, a second electrode pattern (the drain pattern) 120 and four noncontinuous quantum dots 130 linearly arranged between the first electrode pattern 110 and the second electrode pattern 120, as shown FIG. 5. The photoresist layer is developed as shown in FIG. 6a. Due to the optical diffraction, the proximity effect occurs during the lithography. The silicon thin film is etched by reactive ion etching technique to form a quantum island group 210 of two quantum islands 211 and two contacts 213, as shown in FIG. 6b. Three tunnel barriers 212 generate on the periphery of the quantum island 211 as a result of the proximity effect during the lithography. One of the tunnel barriers 212 is positioned between the two quantum islands 211 while the other two tunnel barriers 212 are connected to the contacts 213 respectively. Due to the proximity effect, the two contacts 213 are then connected to the first electrode 220 and the second electrode 230 respectively. As such, the width h of the tunnel barriers 212 is narrower than the width R of the quantum islands 211. Besides, the contacts 213 are formed at the position of the ellipse-shaped quantum dots 130 in FIG. 5. Then, a gate oxide layer is deposited over the silicon thin film so as to further form two polysilicon gates on the gate oxide layer, the polysilicon gates being positioned above the quantum islands 211 in an opposite manner. Consequently, a single electron transistor having two gates, the source and the drain is fabricated.

Although the present invention has been explained in relation to its preferred embodiments, it is to be understood that many other possible modifications and variations can be made without departing from the spirit and scope of the invention as hereinafter claimed.

1. A process for fabricating nanoelectronic devices by intermittent exposure, comprising following steps:
(a) providing a substrate on which a conductor or semiconductor thin film having a photoresist layer coated is formed;
(b) exposing said photoresist layer by lithography with a lithographic pattern which includes at least one noncontinuous quantum dot, a first electrode and a second electrode, wherein said noncontinuous quantum dots are linearly arranged and sandwiched between said first electrode and said second electrode; and
(c) etching said conductor or semiconductor thin film to form a quantum island group of linked quantum islands, said quantum island group having both ends connected to said first electrode and said second electrode respectively;
wherein at least one quantum island and at least two tunnel barriers on the both sides of said quantum island are included and the width of said quantum dots is wider than the width of said tunnel barriers.

2. The process according to claim 1, wherein in step (b) the number of said quantum dots is more than three.

3. The process according to claim 1, wherein in step (b) the shape of said quantum dots is either a circle or an ellipse.

4. The process according to claim 1, wherein in step (b) the size of said quantum dots allow single electrons to pass to form a Coulomb-blockade element of single electron transistor

5. The process according to claim 1, wherein in step (c) said etching is an electron cyclotron resonance (ECR) etching or a reactive ion etching.

6. The process according to claim 1, wherein in step (a) said substrate is a silicon substrate, a glass substrate, a polymer substrate or an organic substrate.

7. The process according to claim 1, wherein in step (a) the material of said conductor or semiconductor thin film is a monocrystalline silicon, a polycrystalline silicon, a metal or a III-V material.

8. The process according to claim 1, further comprising step (d) of forming an oxide insulation layer on said conductor or semiconductor thin film after step (c).

9. The process according to claim 8, further comprising step (e) of forming at least a third electrode on said oxide insulation layer to control the potential of said quantum islands after step (d).

10. The process according to claim 8, wherein in step (c) said first electrode and said second electrode are the drain and the source.

11. The process according to claim 8, wherein said in step (a) said photoresist layer is a negative photoresist material while in step (b) said lithographic pattern is formed by lithographic exposure.

12. The process according to claim 1, wherein in step (a) said lithography is an electron-beam lithography, an X-ray lithography, a micro focused ion beam lithography or a pulsed excimer laser-induced extreme -ultraviolet lithography.

13. A construction of a nanoelectronic device composed of a conductor or semiconductor thin film formed on a substrate, comprising:
a first electrode;
a second electrode;
at least one quantum island formed by lithography to define noncontinuous quantum dots and linearly arranged between said first electrode and said second electrode; and
at least two tunnel barriers formed by the proximity effect of lithography and disposed on the both sides of said quantum island, having a surface width shorter than the surface width of said quantum island to link up with the other quantum island, said first electrode, or said second electrode.

14. The construction according to claim 13, wherein said substrate is a silicon substrate, a glass substrate, a polymer substrate or an organic substrate.

15. The construction according to claim 13 wherein the material of said conductor or semiconductor thin film is a monocrystalline silicon, a polycrystalline silicon, a metal or a III-V material.

16. The construction according to claim 13 wherein an oxide insulation layer is further formed on said conductor or semiconductor thin film.

17. The construction according to claim 16, wherein at least an electrode is further formed on said oxide insulation layer to control the potential of said at least one quantum island.

18. The construction according to claim 13, wherein said lithography is an electron-beam lithography, an X-ray lithography, a micro focused ion beam lithography or a pulsed excimer laser-induced extreme -ultraviolet lithography.

19. The construction according to claim 13 wherein said quantum islands allow a single electron to pass to form a Coulomb-blockade element of a single electron transistor.

20. The construction according to claim 13 wherein said first electrode and said second electrode are the drain and the source.
